(19) United States
(12) Patent Application Publication
(10) Pub. No.: US 2026/0004825 A1
(43) Pub. Date: Jan. 1, 2026

(54) SEMICONDUCTOR DEVICES AND SEMICONDUCTOR SYSTEMS INCLUDING RECEIVER PERFORMING EQUALIZATION OPERATION

(71) Applicant: SK hynix Inc., Icheon-si Gyeonggi-do (KR)

(72) Inventor: Joon Hong PARK, Icheon-si Gyeonggi-do (KR)

(73) Assignee: SK hynix Inc., Icheon-si Gyeonggi-do (KR)

(21) Appl. No.: 18/921,730

(22) Filed: Oct. 21, 2024

(30) Foreign Application Priority Data
Jul. 1, 2024 (KR) 10-2024-0086475

(51) Int. Cl. G11C 7/10

(52) U.S. Cl. CPC G11C 7/1066; G11C 7/1057

(57) ABSTRACT

A semiconductor device includes a clock receiver configured to buffer a data clock signal and an inverted data clock signal to generate a buffer clock signal and an inverted buffer clock signal, respectively, and configured to generate a division clock signal based on the buffer clock signal and the inverted buffer clock signal, and a data receiver configured to buffer data based on the division clock signal to generate internal data.

### CROSS-REFERENCE TO RELATED APPLICATIONS

The present application claims priority under 35 U.S.C. § 119 (a) to Korean Patent Application No. 10-2024-0086475, filed in the Korean Intellectual Property Office on Jul. 1, 2024, the entire contents of which application is incorporated herein by reference.

### BACKGROUND

### 1. Technical Field

Some embodiments of the present disclosure relate to semiconductor devices and semiconductor systems including a receiver performing an equalization operation.

### 2. Related Art

Semiconductor devices perform data input and output operations in synchronization with data strobe signals. Because a voltage level of the data strobe signal input and output to and from the semiconductor device is very small, when a bandwidth of the line through which the data strobe signal is transmitted is not sufficiently secured, inter-symbol interference occurs. The semiconductor devices compensate for distortion caused by the inter-symbol interference by using an equalization circuit, such as continuous time linear equalizer (CTLE) or decision feedback equalizer (DFE).

### SUMMARY

The present disclosure may provide a semiconductor device including a clock receiver configured to buffer a data clock signal and an inverted data clock signal to generate a buffer clock signal and an inverted buffer clock signal, respectively, and configured to generate a division clock signal based on the buffer clock signal and the inverted buffer clock signal, and a data receiver configured to buffer data based on the division clock signal to generate internal data. In the present disclosure, the clock receiver may be configured to perform an equalization operation to reduce a current gain of the buffer clock signal and the inverted buffer clock signal when the buffer control signal is activated, and the clock receiver may stop the equalization operation based on the division clock signal.

In addition, the present disclosure may provide a semiconductor device including a clock buffer circuit configured to, when a buffer control signal is activated, buffer a data clock signal and an inverted data clock signal to generate a buffer clock signal and an inverted buffer clock signal, respectively, and configured to buffer the buffer clock signal and the inverted buffer clock signal to generate an output clock signal and an inverted output clock signal, respectively, and a clock division circuit configured to divide the output clock signal and the inverted output clock signal to generate a division clock signal for buffering data. In the present disclosure, the clock buffer circuit may perform an equalization operation to decrease a current gain of the buffer clock signal and the inverted buffer clock signal when the buffer control signal is activated.

In addition, the present disclosure may provide a semiconductor system including a memory controller configured to output a command address, a data clock signal, an inverted data clock signal, and data, and a semiconductor device configured to generate a buffer control signal based on the command address, when the buffer control signal is activated, buffer the data clock signal and the inverted data clock signal to generate a buffer clock signal and an inverted buffer clock signal, respectively, and buffer the buffer clock signal and the inverted buffer clock signal to generate an output clock signal and an inverted output clock signal, respectively, and divide the output clock signal and the inverted output clock signal to generate a division clock signal for buffering the data. In the present disclosure, the semiconductor device may perform an equalization operation to decrease a current gain of the buffer clock signal and the inverted buffer clock signal when the buffer control signal is activated.

### BRIEF DESCRIPTION OF THE DRAWINGS

FIG. 1 is a block diagram illustrating a semiconductor system according to an embodiment of the present disclosure.

FIG. 2 is a block diagram illustrating a semiconductor device according to an embodiment of the present disclosure.

FIG. 3 is a block diagram illustrating a clock receiver according to an embodiment of the present disclosure.

FIG. 4 is a block diagram illustrating a first clock buffer circuit according to an embodiment of the present disclosure.

FIG. 5 is a block diagram illustrating an equalization control circuit according to an embodiment of the present disclosure.

FIG. 6 is a timing diagram illustrating timing of an operation of an equalization control circuit according to an embodiment of the present disclosure.

FIGS. 7, 8, and 9 are diagrams illustrating an operation of an equalization control circuit according to an embodiment of the present disclosure.

FIG. 10 is a block diagram illustrating a clock driving circuit according to an embodiment of the present disclosure.

FIG. 11 is a circuit diagram of a clock driving circuit according to an embodiment of the present disclosure.

FIG. 12 illustrates waveforms of a buffer clock signal and an inverted buffer clock signal when an equalization operation is not performed in a clock driving circuit according to an embodiment of the present disclosure.

FIG. 13 illustrates waveforms of a buffer clock signal and an inverted buffer clock signal when an equalization operation is performed in a clock driving circuit according to an embodiment of the present disclosure.

FIG. 14 is a timing diagram illustrating jitter phenomenon of an output clock signal generated in a clock receiver according to an embodiment of the present disclosure.

FIG. 15 is a timing diagram illustrating a division clock signal generated in a clock receiver according to an embodiment of the present disclosure.

### DETAILED DESCRIPTION

In the following description of embodiments, when a parameter is referred to as being “predetermined,” a value of the parameter may be determined in advance when the parameter is used in a process or an algorithm. The value of the parameter may be determined when the process or the algorithm starts or may be determined during a period in which the process or the algorithm is executed.

Although the terms “first,” “second,” “third,” and so forth are used herein to describe various elements, these elements should not be limited by these terms. These terms are only used to distinguish one element from another element and are not intended to imply an order or number of elements. Thus, a first element in some embodiments may be termed a second element in other embodiments without departing from the teachings of the present disclosure.

When an element is referred to as “connected” or “coupled” to another element, the element may be directly connected or coupled to the other element or intervening elements may be present. When an element is referred to as “directly connected” or “directly coupled” to another element, no intervening elements are present.

A logic “high” level and a logic “low” level may be used to describe logic levels of electric signals. A signal at a logic “high” level is distinguished from a signal at a logic “low” level. For example, when a signal at a first voltage corresponds to a signal at a logic “high” level, a signal at a second voltage corresponds to a signal at a logic “low” level. In an embodiment, the logic “high” level may be a voltage level that is higher than a voltage level of the logic “low” level. Logic levels of signals may be different or opposite according to the embodiments. For example, a certain signal at a logic “high” level in one embodiment may be at a logic “low” level in another embodiment.

The term “logic bit set” may include a combination of logic levels of bits included in a signal. When the logic level of each of the bits included in the signal is changed, the logic bit set of the signal may be different. For example, when the signal includes two bits, when the logic level of each of the two bits included in the signal is “logic low level, logic low level,” the logic bit set of the signal may be the first logic bit set, and when the logic level of each of the two bits included in the signal is “a logic low level and a logic high level,” the logic bit set of the signal may be the second logic bit set.

Various embodiments of the present disclosure are described in more detail with reference to the accompanying drawings. The embodiments are described for illustrative purposes only and are not intended to limit the scope of the present disclosure.

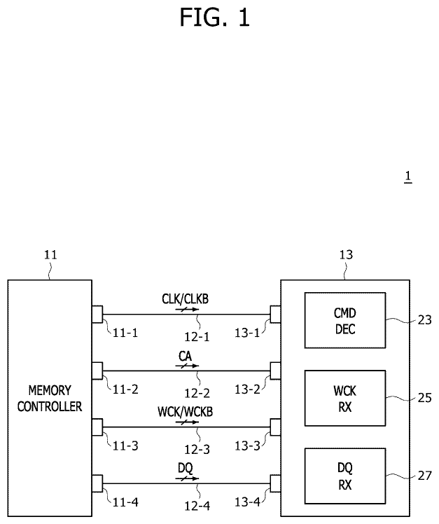

FIG. 1 is a block diagram illustrating a semiconductor system 1 according to an embodiment of the present disclosure. As shown in FIG. 1, the semiconductor system 1 may include a memory controller 11 and a semiconductor device 13.

The memory controller 11 may include a first control pin 11-1, a second control pin 11-2, a third control pin 11-3, and a fourth control pin 11-4. The semiconductor device 13 may include a first device pin 13-1, a second device pin 13-2, a third device pin 13-3, and a fourth device pin 13-4. The memory controller 11 may transmit a clock signal CLK and an inverted clock signal CLKB to the semiconductor device 13 through a first transmission line 12-1 connected between the first control pin 11-1 and the first device pin 13-1. The memory controller 11 may provide a command address CA to the semiconductor device 13 through a second transmission line 12-2 connected between the second control pin 11-2 and the second device pin 13-2. The number of second control pins 11_2, the second transmission lines 12_2, and the second device pins 13_2 may be vary depending on the number of bits of the command address CA. The memory controller 11 may provide a data clock signal WCK and an inverted data clock signal WCKB to the semiconductor device 13 through a third transmission line 12-3 connected between the third control pin 11-3 and the third device pin 13-3. The memory controller 11 may provide data DQ to the semiconductor device 13 through a fourth transmission line 12-4 connected between the fourth control pin 11-4 and the fourth device pin 13-4. The number of fourth control pins 11-4, fourth device pins 13-4, and fourth transmission lines 12-4 may vary depending on the number of bits of the data DQ.

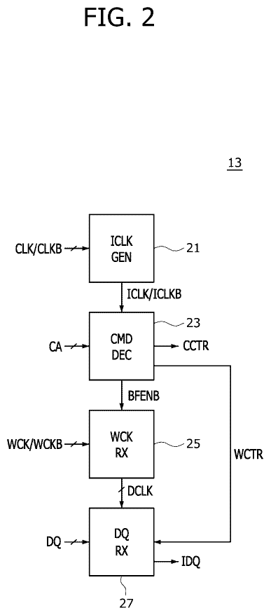

The semiconductor device 13 may include a command decoder (CMD DEC) 23, a clock receiver (WCK RX) 25, and a data receiver (DQ RX) 27. The command decoder 23 may decode the command address CA to control the activation of the clock receiver 25 that receives the data clock signal WCK and the inverted data clock signal WCKB. The clock receiver 25 may buffer the data clock signal WCK and the inverted data clock signal WCKB to generate a division clock signal (DCLK of FIG. 2). The clock receiver 25 may reduce the difference in voltage levels of the buffered clock signals through an equalization operation when buffering the data clock signal WCK and the inverted data clock signal WCKB to quickly set the speed at which the voltage level transitions. The clock receiver 25 may stop the equalization operation to reduce current consumption when the data clock signal WCK and the inverted data clock signal WCKB are buffered to generate the division clock signal (DCLK in FIG. 2). The data receiver 27 may buffer the data DQ, based on the division clock signal (DCLK in FIG. 2), to generate internal data IDQ in a write operation.

FIG. 2 is a block diagram illustrating an embodiment of the semiconductor device 13 such as shown in FIG. 1.

As shown in FIG. 2, the semiconductor device 13 may include an internal clock generating circuit (ICLK GEN) 21, the command decoder (CMD DEC) 23, the clock receiver (WCK RX) 25, and the data receiver (DQ RX) 27.

The internal clock generating circuit 21 may generate an internal clock signal ICLK and an inverted internal clock signal ICLKB, based on the clock signal CLK and the inverted clock signal CLKB. The internal clock generating circuit 21 may buffer the clock signal CLK to generate the internal clock signal ICLK. The internal clock generating circuit 21 may buffer the inverted clock signal CLKB to generate the inverted internal clock signal ICLKB.

The command decoder 23 may be electrically connected to the internal clock generating circuit 21, and the command decoder 23 may receive the internal clock signal ICLK and the inverted internal clock signal ICLKB from the internal clock generating circuit 21. The command decoder 23 may decode the command address CA, based on the internal clock signal ICLK and the inverted internal clock signal ICLKB, to generate a core control signal CCTR, a write control signal WCTR, and a buffer control signal BFENB. The core control signal CCTR may be generated for a write operation that stores data in memory cells (not shown) or a read operation that outputs the data stored in the memory cells (not shown). The write control signal WCTR may be generated to receive the data DQ in the write operation. The buffer control signal BFENB may be generated to activate the clock receiver 25 that receives the data clock signal WCK and the inverted data clock signal WCKB in the write operation or the read operation. The command decoder 23 may generate the core control signal CCTR that is activated when the bits included in the command address CA are in a first bit set in synchronization with the internal clock signal ICLK and the inverted internal clock signal ICLKB. The command decoder 23 may generate the write control signal WCTR that is activated when the bits included in the command address CA are in a second bit set in synchronization with the internal clock signal ICLK and the inverted internal clock signal ICLKB. The command decoder 23 may generate the buffer control signal BFENB that is activated when the bits included in the command address CA are in a third bit set in synchronization with the internal clock signal ICLK and the inverted internal clock signal ICLKB.

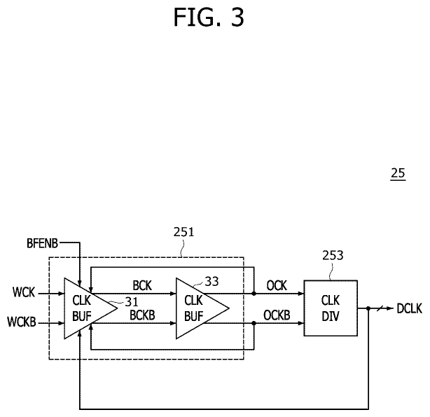

The clock receiver 25 may be electrically connected to the command decoder 23 and receives the buffer control signal BFENB from the command decoder 23. The clock receiver 25 may generate the division clock signal DCLK based on the buffer control signal BFENB, the data clock signal WCK, and the inverted data clock signal WCKB. The clock receiver 25 may generate the division clock signal DCLK, which is a four divisions of the data clock signal WCK. A cycle of the division clock signal DCLK may be set to be 4 times larger than a cycle of the data clock signal WCK. When the buffer control signal BFENB is activated, the clock receiver 25 may buffer the data clock signal WCK and the inverted data clock signal WCKB to generate a buffer clock signal (BCK in FIG. 3) and an inverted buffer clock signal (BCKB in FIG. 3). After the buffer control signal BFENB is activated, the clock receiver 25 may receive an output clock signal (OCK in FIG. 3) and an inverted output clock signal (OCKB in FIG. 3) to perform an equalization operation. The clock receiver 25 may perform the equalization operation to generate the buffer clock signal (BCK in FIG. 3) and the inverted buffer clock signal (BCKB in FIG. 3) with decreased DC gain. A decrease in the DC gain of the buffer clock signal (BCK in FIG. 3) and the inverted buffer clock signal (BCKB in FIG. 3) may mean that the difference in voltage level between the buffer clock signal (BCK in FIG. 3) and the inverted buffer clock signal (BCKB in FIG. 3) is reduced. The clock receiver 25 may buffer the buffer clock signal (BCK in FIG. 3) and the inverted buffer clock signal (BCKB in FIG. 3) to generate the output clock signal (OCK in FIG. 3) and the inverted output clock signal (OCKB in FIG. 3). The clock receiver 25 may perform the normalization operation to generate the output clock signal (OCK in FIG. 3) and the inverted output clock signal (OCKB in FIG. 3) with an increased speed at which the voltage levels transition. In addition, the clock receiver 25 may stop the equalization operation after the division clock signal DCLK is generated to reduce current consumption.

The data receiver 27 may be electrically connected to the command decoder 23 and the clock receiver 25. The data receiver 27 may receive the write control signal WCTR from the command decoder 23 and may receive the division clock signal DCLK from the clock receiver 25. The data receiver 27 may buffer the data DQ, based on the division clock signal DCLK, to generate internal data IDQ when the write control signal WCTR is activated in the write operation. The division clock signal DCLK may include a plurality of division clock signals. For example, the division clock signal DCLK may include a first division clock signal DCLK1, a second division clock signal DCLK2, a third division clock signal DCLK3, and a fourth division clock signal DCLK4. The data receiver 27 may align the data DQ to generate the internal data IDQ in synchronization with the first division clock signal DCLK1, the second division clock signal DCLK2, the third division clock signal DCLK3, and the fourth division clock signal DCLK4. The first division clock signal DCLK1, the second division clock signal DCLK2, the third division clock signal DCLK3, and the fourth division clock signal DCLK4 may be set to have a phase difference of 90° from each other.

FIG. 3 is a block diagram illustrating an embodiment of the clock receiver 25 such as shown in FIG. 2.

As shown in FIG. 3, the clock receiver 25 may include a clock buffer circuit 251 and a clock division circuit (CLK DIV) 253.

When the buffer control signal BFENB is activated, the clock buffer circuit 251 may buffer the data clock signal WCK and the inverted data clock signal WCKB to generate the buffer clock signal BCK and the inverted buffer clock signal BCKB and may buffer the buffer clock signal BCK and the inverted buffer clock signal BCKB to generate the output clock signal OCK and the inverted output clock signal OCKB. After the buffer control signal BFENB is activated, the clock buffer circuit 251 may perform an equalization operation, based on the output clock signal OCK and the inverted output clock signal OCKB, to generate the buffer clock signal BCK and the inverted buffer clock signal BCKB with decreased DC gain. The clock buffer circuit 251 may increase the speed at which the voltage levels of the output clock signal OCK and the inverted output clock signal OCKB transition due to the equalization operation. The clock buffer circuit 251 may stop the equalization operation to reduce current consumption when the division clock signal DCLK is generated. The clock buffer circuit 251 may include a first clock buffer circuit (CLK BUF) 31 and a second clock buffer circuit (CLK BUF) 33.

The first clock buffer circuit 31 may buffer the data clock signal WCK and the inverted data clock signal WCKB, based on the buffer control signal BFENB, to generate the buffer clock signal BCK and the inverted buffer clock signal BCKB. When the buffer control signal BFENB is activated, the first clock buffer circuit 31 may buffer the data clock signal WCK to generate the buffer clock signal BCK and may buffer the inverted data clock signal WCKB to generate the inverted buffer clock signal BCKB. After the buffer control signal BFENB is activated, the first clock buffer circuit 31 may receive the output clock signal OCK and the inverted output clock signal OCKB as feedback from the second clock buffer circuit 33. The first clock buffer circuit 31 may perform an equalization operation based on the output clock signal OCK and the inverted output clock signal OCKB to generate the buffer clock signal BCK and the inverted buffer clock signal BCKB with decreased DC gain. The first clock buffer circuit 31 may stop the equalization operation to decrease current consumption when the first division clock signal DCLK1 is generated.

The second clock buffer circuit 33 may be electrically connected to the first clock buffer circuit 31 and may receive the buffer clock signal BCK and the inverted buffer clock signal BCKB from the first clock buffer circuit 31. The second clock buffer circuit 33 may buffer the buffer clock signal BCK and the inverted buffer clock signal BCKB to generate the output clock signal OCK and the inverted output clock signal OCKB. The second clock buffer circuit 33 may buffer the buffer clock signal BCK to generate the output clock signal OCK and may buffer the inverted buffer clock signal BCKB to generate the inverted output clock signal OCKB. When the buffer clock signal BCK and the inverted buffer clock signal BCKB with decreased DC gain are generated by the equalization operation of the first clock buffer circuit 31, the second clock buffer circuit 33 may generate the output clock signal OCK and the inverted output clock signal OCKB, the voltage levels of which transition at a fast speed.

The clock division circuit 253 may be electrically connected to the second clock buffer circuit 33 and may receive the output clock signal OCK and the inverted output clock signal OCKB from the second clock buffer circuit 33. The clock division circuit 253 may divide the output clock signal OCK and the inverted output clock signal OCKB to generate the division clock signal DCLK. The division clock signal DCLK may be set to a four-division signal, the cycle of which is set to be four times greater than a cycle of each of the output clock signal OAK and the inverted output clock signal OAKB. The division clock signal DCLK may include the first division clock signal DCLK1, the second division clock signal DCLK2, the third division clock signal DCLK3, and the fourth division clock signal DCLK4 that are set to have a phase difference of 90° when comparing one division clock signal with the subsequent division clock signal (i.e., comparing the second and third division clock signals, comparing fourth and first division clock signals, etc.).

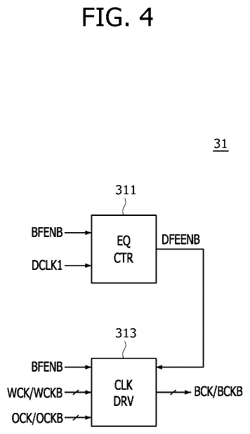

FIG. 4 is a block diagram illustrating an embodiment of the first clock buffer circuit 31, such as shown in FIG. 3. As shown in FIG. 4, the first clock buffer circuit 31 may include an equalization control circuit (EQ CTR) 311 and a clock driving circuit (CLK DRV) 313.

The equalization control circuit 311 may generate an equalization control signal DFEENB based on the buffer control signal BFENB and the first division clock signal DCLK1. When the buffer control signal BFENB is activated, the equalization control circuit 311 may generate the equalization control signal DFEENB that is activated. As an example, when a write operation is performed and the buffer control signal BFENB is activated, the equalization control circuit 311 may generate the equalization control signal DFEENB that is activated for the equalization operation. When the first division clock signal DCLK1 is generated, the equalization control circuit 311 may generate the equalization control signal DFEENB that is deactivated. After the buffer control signal BFENB is activated, the equalization control circuit 311 may generate the equalization control signal DFEENB that is deactivated when the first division clock signal DCLK1 is generated by the clock division circuit 253 based on the output clock signal OCK and the inverted output clock signal OCKB.

The clock driving circuit 313 may be electrically connected to the equalization control circuit 311 and may receive the equalization control signal DFEENB from the equalization control circuit 311. The clock driving circuit 313 may generate the buffer clock signal BCK and the inverted buffer clock signal BCKB, based on the buffer control signal BFENB, the equalization control signal DFEENB, the data clock signal WCK, the inverted data clock signal WCKB, the output clock signal OCK, and the inverted output clock signal OCKB. When the buffer control signal BFENB is activated, the clock driving circuit 313 may buffer the data clock signal WCK and the inverted data clock signal WCKB to generate the buffer clock signal BCK and the inverted buffer clock signal BCKB. After the buffer control signal BFENB is activated, the clock driving circuit 313 may perform the equalization operation when the equalization control signal DFEENB is activated. When the equalization operation is performed, the clock driving circuit 313 may generate the buffer clock signal BCK and the inverted buffer clock signal BCKB with decreased DC gain based on the output clock signal OCK and the inverted output clock signal OCKB.

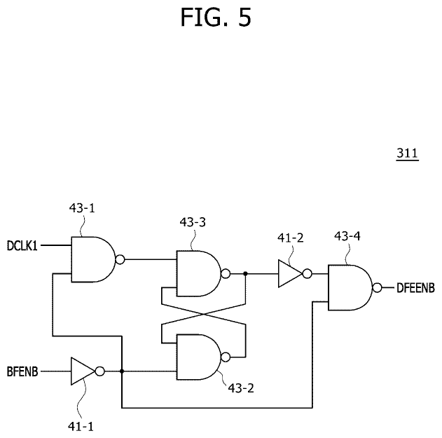

FIG. 5 is a block diagram illustrating an embodiment of the equalization control circuit 311, such as shown in FIG. 4.

As shown in FIG. 5, the equalization control circuit 311 may include inverters 41-1 and 41-2, and NAND gates 43-1, 43-2, 43-3, and 43-4. The inverter 41-1 may inversely buffer the buffer control signal BFENB to output an inversely buffered signal of the buffer control signal BFENB. The NAND gate 43-1 may receive the first division clock signal DCLK1 and an output signal of the inverter 41-1 to perform a NAND operation. The NAND gate 43-2 may receive the output signal of the inverter 41-1 and an output signal of the NAND gate 43-3 to perform a NAND operation. The NAND gate 43-3 may receive the output signal of the inverter 41-1 and the output signal of the NAND gate 43-2 to perform a NAND operation. The inverter 41-2 may inversely buffer the output signal of the NAND gate 43-3 to output an inversely buffered signal of the output signal of the NAND gate 43-3. The NAND gate 43-4 may receive the output signal of the inverter 41-1 and the output signal of the inverter 41-2 and may perform a NAND operation to generate the equalization control signal DFEENB. The equalization control circuit 311 may generate the equalization control signal DFEENB that is activated when the buffer control signal BFENB is activated. The equalization control circuit 311 may generate the equalization control signal DFEENB that is deactivated when the first division clock signal DCLK1 is generated after the buffer control signal BFENB is activated.

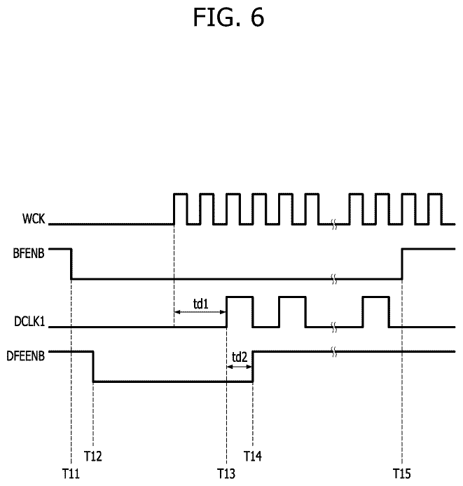

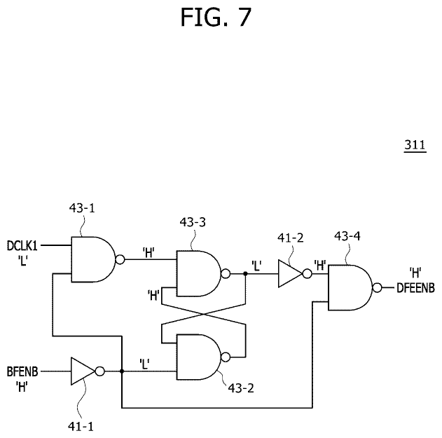

FIG. 6 is a timing diagram illustrating timing of an operation of the equalization control circuit 311 according to an embodiment of the present disclosure, such as shown in FIG. 5. FIGS. 7, 8, and 9 are diagrams illustrating the operation of the equalization control circuit 311. The operation of the equalization control circuit 311 is described with reference to FIGS. 6, 7, 8, and 9 as follows.

Referring to FIG. 6 and FIG. 7, during a period before T11, while the first division clock signal DCLK1 is not being generated and is set to a logic “low” level ‘L’ and the buffer control signal BFENB is deactivated at logic “high” level ‘H’, the output signal of the inverter 41-1 may be set to a logic “low” level ‘L’, and the output signal of the NAND gate 43-1 may be set to a logic “high” level ‘H’. The output signal of the NAND gate 43-3 may be set to a logic “low” level ‘L’ according to the output signal of the NAND gate 43-1 and the output signal of the NAND gate 43-2, which are all set to a logic “high” level ‘H’. The equalization control signal DFEENB output from the NAND gate 43-4 may be generated in a deactivated state at a logic “high” level ‘H’ according to the output signal of the inverter 41-1 set to a logic “low” level ‘L’.

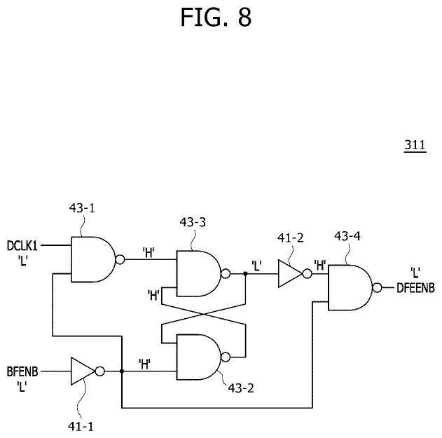

Referring to FIG. 6 and FIG. 8, at time T11, when the buffer control signal BFENB is activated at a logic “low” level ‘L’, the output signal of the inverter 41-1 may be set to a logic “high” level ‘H’, and the output signal of the NAND gate 43-1 may be set to a logic “high” level ‘H’. The output signal of the NAND gate 43-3 may be set to a logic “low” level ‘L’ according to the output signal of the NAND gate 43-1 and the output signal of the NAND gate 43-2, which are all set to a logic “high” level ‘H’. The equalization control signal DFEENB output from the NAND gate 43-4 may be generated in an activated state at a logic “low” level ‘L’ by the output signal of the inverter 41-1 and the output signal of the inverter 41-2, which are both set to a logic “high” level ‘H’.

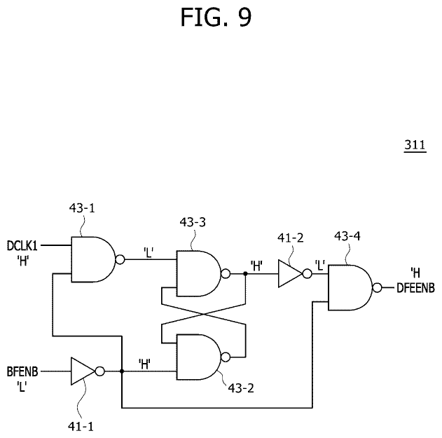

Referring to FIG. 6 and FIG. 9, after the equalization control signal DFEENB is activated at logic “low” level ‘L’ at time T12, the first division clock signal DCLK1 may be generated from time T13 at which a first time period td1 elapses from a time at which the write clock signal WCK is generated. Because the output signal of the NAND gate 43-1 is set to a logic “low” level ‘L’ when the first division clock signal DCLK1 is generated at logic “high” level ‘H’, the output signal of the NAND gate 43-3 may be set to a logic “high” level ‘H’, and the output signal of the inverter 41-2 may be set to a logic “low” level ‘L’. When a second time period td2 elapses from the time at which the first division clock signal DCLK1 is generated according to the output signal of the inverter 41-2 set to a logic “low” level ‘L’, the equalization control signal DFEENB output from the NAND gate 43-4 may be generated in a deactivated state at logic “high” level ‘H’ at time T14.

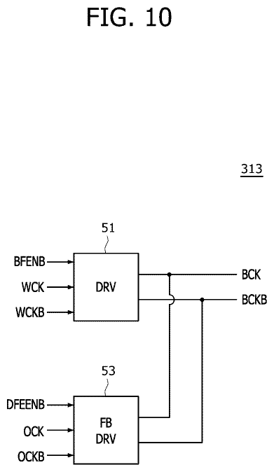

FIG. 10 is a block diagram illustrating an embodiment of the clock driving circuit 313, such as shown in FIG. 4.

As shown in FIG. 10, the clock driving circuit 313 may include a driving circuit (DRV) 51 and a feedback driving circuit (FB DRV) 53.

The driving circuit 51 may drive the buffer clock signal BCK and the inverted buffer clock signal BCKB, based on the buffer control signal BFENB, the data clock signal WCK, and the inverted data clock signal WCKB. When the buffer control signal BFENB is activated, the driving circuit 51 may drive the inverted buffer clock signal BCKB according to the data clock WCK and may drive the buffer clock signal BCK according to the inverted data clock signal WCKB. The driving circuit 51 may drive the buffer clock signal BCK with the same phase as the data clock signal WCK and may drive the inverted buffer clock signal BCKB with the same phase as the inverted data clock signal WCKB.

The feedback driving circuit 53 may drive the buffer clock signal BCK and the inverted buffer clock signal BCKB, based on the equalization control signal DFEENB, the output clock signal OCK, and the inverted output clock signal OCKB. When the equalization control signal DFEENB is activated, the feedback driving circuit 53 may drive the inverted buffer clock signal BCKB according to the inverted output clock signal OCKB and may drive the buffer clock signal BCKB according to the output clock signal OCK. The feedback driving circuit 53 may drive the buffer clock signal BCK with the same phase as the inverted output clock signal OCKB and may drive the inverted buffer clock signal BCKB with the same phase as the output clock signal OCK.

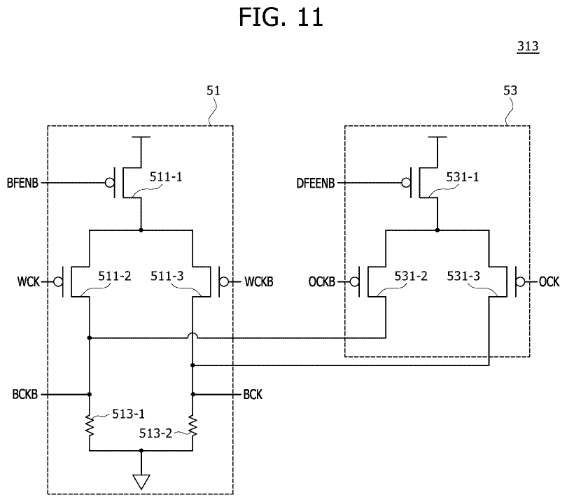

FIG. 11 is a circuit diagram of an embodiment of the clock driving circuit 313, such as shown in FIG. 10.

As shown in FIG. 11, the clock driving circuit 313 may include the driving circuit 51 and the feedback driving circuit 53.

The driving circuit 51 may include PMOS transistors 511-1, 511-2, and 511-3 and resistor elements 513-1 and 513-2. The PMOS transistor 511-1 may be turned on when the buffer control signal BFENB is activated at a logic “low” level. The PMOS transistor 511-2 may be turned on when the data clock signal WCK is at a logic “low” level, and the PMOS transistor 511-3 may be turned on when the inverted data clock signal WCKB is at a logic “low” level. The driving circuit 51 may drive the buffer clock signal BCK with the same phase as the data clock signal WCK and may drive the inverted buffer clock signal BCKB with the same phase as the inverted data clock signal WCKB.

The feedback driving circuit 53 may include PMOS transistors 531-1, 531-2, and 531-3. The PMOS transistor 531-1 may be turned on when the equalization control signal DFEENB is activated at a logic “low” level. The PMOS transistor 531-2 may be turned on when the inverted output clock signal OCKB is at a logic “low” level, and the PMOS transistor 531-3 may be turned on when the output clock signal OCK is at a logic “low” level. The feedback driving circuit 53 may drive the buffer clock signal BCK with the same phase as the inverted output clock signal OCKB and may drive the inverted buffer clock signal BCKB with the same phase as the output clock signal OCK.

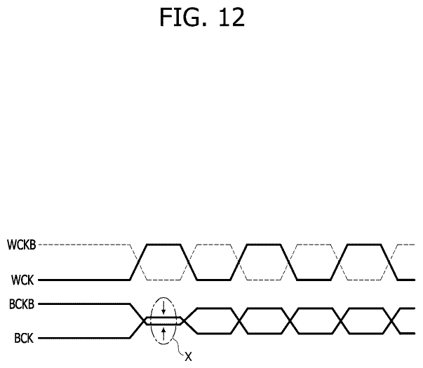

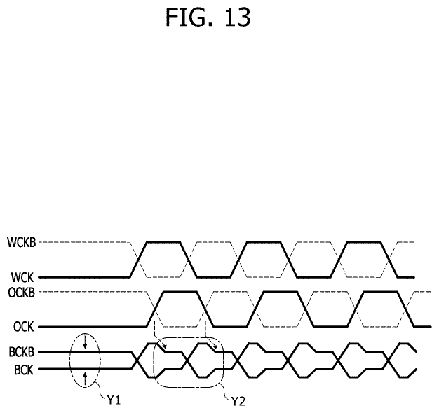

FIG. 12 illustrates waveforms of the buffer clock signal BCK and the inverted buffer clock signal BCKB when an equalization operation is not performed in the clock driving circuit 313. FIG. 13 illustrates the waveforms of the buffer clock signal BCK and the inverted buffer clock signal BCKB when the equalization operation is performed in the clock driving circuit 313.

As shown in FIG. 12, in a case in which an equalization operation is not performed in the clock driving circuit 313, when the data clock signal WCK and the inverted data clock signal WCKB are toggled in a static state, a state (X) may occur in which first toggling is not performed properly when the buffer clock signal BCK and the inverted buffer clock signal BCKB, generated by the clock driving circuit 313 by buffering the data clock signal WCK and the inverted data clock signal WCKB, toggle.

As shown in FIG. 13, in a case in which the equalization operation is performed, the buffer clock signal BCK and the inverted buffer clock signal BCKB, generated by the clock driving circuit 313 by buffering the data clock signal WCK and the inverted data clock signal WCKB, in a static state may be generated with a decreased DC gain Y1. Additionally, when the equalization operation is performed, the buffer clock signal BCK and the inverted buffer clock signal BCKB may be buffered to generate the output clock signal OCK and the inverted output clock signal OCKB, the voltage levels of which transition at a high speed. The buffer clock signal BCK and the inverted buffer clock signal BCKB, generated when the equalization operation is performed, may have a decreased DC gain Y2 in a low-frequency state in which the voltage levels are maintained after the voltage levels transition so that the voltage levels of the output clock signal OCK and the inverted output clock signal OCKB can transition at a high speed.

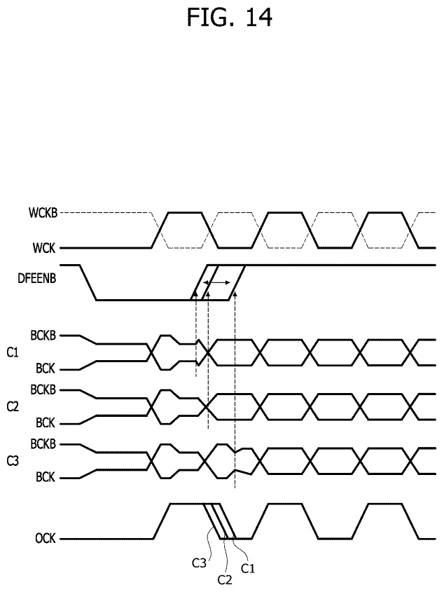

FIG. 14 is a timing diagram illustrating jitter phenomenon of an output clock signal generated in the clock receiver 25, such as shown in FIG. 2.

Referring to FIG. 14, as a time period in which the equalization operation is performed (i.e., in which the equalization control signal DFEENB is activated at a logic “low” level) changes, a jitter phenomenon occurring in the output clock signal OCK may be detected. When the time period in which the equalization operation is performed changes in the order of a first case C1, a second case C2, and a third case C3, the time period in which the DC gain of the buffer clock signal BCK and the inverted buffer clock signal BCKB decreases may increase in the order of the first case C1, the second case C2, and the third case C3. The voltage level of the output clock signal OCK may transition faster as the period in which the DC gain of the buffer clock signal BCK and the inverted buffer clock signal BCKB decreases becomes longer. Accordingly, the timing at which the voltage level of the output clock signal OCK transitions from a logic “high” level to a logic “low” level may be delayed in the order of the first case C1, the second case C2, and the third case C3, resulting in the jitter phenomenon.

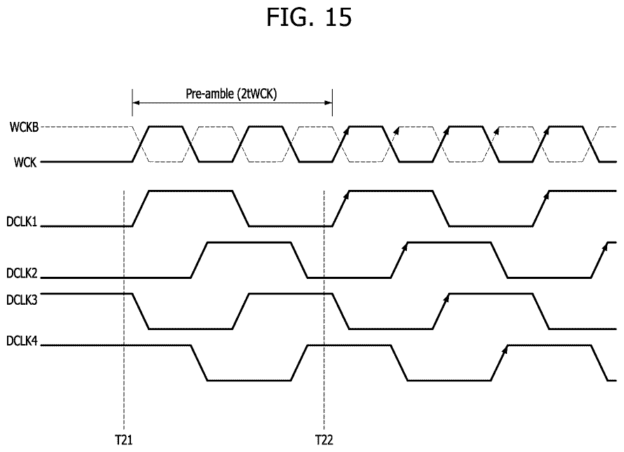

FIG. 15 is a timing diagram illustrating the division clock signal generated in the clock receiver 25, such as shown in FIG. 4.

FIG. 15 illustrates the waveforms of the first division clock signal DCLK1, the second division clock signal DCLK2, the third division clock signal DCLK3, and the fourth division clock signal DCLK4 that are generated by the clock receiver 25 by buffering the data clock signal WCK and the inverted data clock signal WCKB. During the preamble period set to 2 cycles 2tWCK, the first division clock signal DCLK1, the second division clock signal DCLK2, the third division clock signal DCLK3, and the fourth division clock signal DCLK4 may be affected by a jitter phenomenon occurring in the output clock signal OCK as the period in which the equalization operation is performed changes in FIG. 14. However, because the first division clock signal DCLK1, the second division clock signal DCLK2, the third division clock signal DCLK3, and the fourth division clock signal DCLK4 are not used to buffer the data DQ in the data receiver 27 during the preamble period, the influence of the jitter phenomenon that occurs in the output clock signal OCK during the preamble period might not be considered.

Concepts are disclosed in conjunction with various embodiments as described above. Those skilled in the art will understand that various modifications, additions, and substitutions are possible, without departing from the scope and spirit of the present disclosure. Accordingly, the embodiments disclosed in the present specification should not be considered from a restrictive standpoint but rather from an illustrative standpoint. The scope of the present disclosure is not limited to the above descriptions, and all of distinctive features within an equivalent scope should be construed as being included in the present disclosure.

What is claimed is:

1. A semiconductor device comprising:
a clock receiver configured to buffer a data clock signal and an inverted data clock signal to generate a buffer clock signal and an inverted buffer clock signal, respectively, and configured to generate a division clock signal based on the buffer clock signal and the inverted buffer clock signal; and
a data receiver configured to buffer data based on the division clock signal to generate internal data,
wherein the clock receiver is configured to perform an equalization operation to reduce a current gain of the buffer clock signal and the inverted buffer clock signal when the buffer control signal is activated, and
wherein the clock receiver stops the equalization operation based on the division clock signal.

2. The semiconductor device of claim 1, further comprising a command decoder configured to decode a command address to generate the buffer control signal that activates the clock receiver in a write operation or a read operation.

3. The semiconductor device of claim 1, wherein the clock receiver is configured to decrease a difference in voltage levels of the buffer clock signal and the inverted buffer clock signal in a static state and a low frequency state when the equalization operation is performed.

4. The semiconductor device of claim 1, wherein the clock receiver comprises:
a first clock buffer circuit configured to buffer the data clock signal and the inverted data clock signal to generate the buffer clock signal and the inverted buffer clock signal, respectively, when the buffer control signal is activated; and
a second clock buffer circuit configured to buffer the buffer clock signal and the inverted buffer clock signal to generate an output clock signal and an inverted output clock signal, respectively.

5. The semiconductor device of claim 4, wherein the first clock buffer circuit receives the output clock signal and the inverted output clock signal as feedback.

6. The semiconductor device of claim 4, wherein the second clock buffer circuit generates the output clock signal and inverted output clock signal whose voltage level transition speed is increased when a current gain of the buffer clock signal and the inverted buffer clock signal is decreased through the equalization operation.

7. The semiconductor device of claim 4, further comprising a clock division circuit configured to divide the output clock signal and the inverted output clock signal to generate the division clock signal.

8. The semiconductor device of claim 7,
wherein the division clock signal includes a plurality of division clock signals, and
wherein the first clock buffer circuit stops the equalization operation based on one of the division clock signals.

9. The semiconductor device of claim 4, wherein the first clock buffer circuit comprises:
an equalization control circuit configured to generate an equalization control based on the buffer control signal and the division clock signal; and
a clock driving circuit configured to generate the buffer clock signal and the inverted buffer clock signal based on the buffer control signal, the equalization control signal, the data clock signal, the inverted data clock signal, the output clock signal, and the inverted output clock signal.

10. The semiconductor device of claim 9, wherein the equalization control circuit is configured to:
generate the equalization control signal that is activated when the buffer control signal is activated, and
generate the equalization control signal that is deactivated when the division clock is generated.

11. The semiconductor device of claim 9, wherein the clock driving circuit comprises:
a driving circuit configured to drive the buffer clock signal and the inverted buffer clock signal, based on the buffer control signal, the data clock signal, and the inverted data clock signal; and
a feedback driving circuit configured to drive the buffer clock signal and the inverted buffer clock signal, based on the equalization control signal, the output clock signal, and the inverted output clock signal.

12. The semiconductor device of claim 11, wherein the driving circuit is configured to:
drive the buffer clock signal with the same phase as the data clock signal, and
drive the inverted buffer clock signal with the same phase as the inverted data clock signal.

13. The semiconductor device of claim 11, wherein the feedback driving circuit is configured to:
drive the buffer clock signal with the same phase as the inverted output clock signal, and
drive the inverted buffer clock signal with the same phase as the output clock signal.

14. A semiconductor device comprising:
a clock buffer circuit configured to, when a buffer control signal is activated, buffer a data clock signal and an inverted data clock signal to generate a buffer clock signal and an inverted buffer clock signal, respectively, and configured to buffer the buffer clock signal and the inverted buffer clock signal to generate an output clock signal and an inverted output clock signal, respectively; and
a clock division circuit configured to divide the output clock signal and the inverted output clock signal to generate a division clock signal for buffering data,
wherein the clock buffer circuit performs an equalization operation to decrease a current gain of the buffer clock signal and the inverted buffer clock signal when the buffer control signal is activated.

15. The semiconductor device of claim 14, further comprising a command decoder configured to decode a command address to generate the buffer control signal that activates the clock receiver in a write operation or a read operation.

16. The semiconductor device of claim 14, wherein the clock buffer circuit is configured to decrease a difference in voltage levels of the buffer clock signal and the inverted buffer clock signal in a static state and a low frequency state when the equalization operation is performed.

17. The semiconductor device of claim 14, wherein the clock buffer circuit comprises:
a first clock buffer circuit configured to buffer the data clock signal and the inverted data clock signal to generate the buffer clock signal and the inverted buffer clock signal, respectively, when the buffer control signal is activated; and
a second clock buffer circuit configured to buffer the buffer clock signal and the inverted buffer clock signal to generate the output clock signal and the inverted output clock signal, respectively.

18. The semiconductor device of claim 17, wherein the first clock buffer circuit receives the output clock signal and the inverted output clock signal as feedback.

19. The semiconductor device of claim 17, wherein the second clock buffer circuit is configured to generate the output clock signal and inverted output clock signal, voltage level transition speeds of which are increased when the current gain of the buffer clock signal and the inverted buffer clock signal is decreased through the equalization operation.

20. The semiconductor device of claim 17, wherein the first clock buffer circuit stops the equalization operation based on the division clock signal.

21. The semiconductor device of claim 17, wherein the first clock buffer circuit comprises:
an equalization control circuit configured to generate an equalization control signal based on the buffer control signal and the division clock signal; and
a clock driving circuit configured to generate the buffer clock signal and the inverted buffer clock signal, based on the buffer control signal, the equalization control signal, the data clock signal, the inverted data clock signal, the output clock signal, and the inverted output clock signal.

22. The semiconductor device of claim 21, wherein the equalization control circuit is configured to:
generate the equalization control signal that is activated when the buffer control signal is activated, and
generate the equalization control signal that is deactivated when the division clock is generated.

23. The semiconductor device of claim 21, wherein the clock driving circuit comprises:
a driving circuit configured to drive the buffer clock signal and the inverted buffer clock signal, based on the buffer control signal, the data clock signal, and the inverted data clock signal; and
a feedback driving circuit configured to drive the buffer clock signal and the inverted buffer clock signal, based on the equalization control signal, the output clock signal, and the inverted output clock signal.

24. The semiconductor device of claim 23, wherein the driving circuit is configured to:
drive the buffer clock signal with the same phase as the data clock signal, and
drive the inverted buffer clock signal with the same phase as the inverted data clock signal.

25. The semiconductor device of claim 23, wherein the feedback driving circuit is configured to:
drive the buffer clock signal with the same phase as the inverted output clock signal, and
drive the inverted buffer clock signal with the same phase as the output clock signal.

26. A semiconductor system comprising:
a memory controller configured to output a command address, a data clock signal, an inverted data clock signal, and data; and
a semiconductor device configured to:
generate a buffer control signal based on the command address,
when the buffer control signal is activated, buffer the data clock signal and the inverted data clock signal to generate a buffer clock signal and an inverted buffer clock signal, respectively, and buffer the buffer clock signal and the inverted buffer clock signal to generate an output clock signal and an inverted output clock signal, respectively, and
divide the output clock signal and the inverted output clock signal to generate a division clock signal for buffering the data,
wherein the semiconductor device performs an equalization operation to decrease a current gain of the buffer clock signal and the inverted buffer clock signal when the buffer control signal is activated.
